(19) United States
(12) Patent Application Publication
(10) Pub. No.: US 2024/0042482 A1
(43) Pub. Date: Feb. 8, 2024

(54) EVAPORATION SYSTEM HAVING IMPROVED COLLIMATION

(71) Applicant: eMagin Corporation, Hopewell Junction, NY (US)

(72) Inventors: Fridrich VAZAN, Pittsford, NY (US); Ilyas I. KHAYRULLIN, Hopewell Junction, NY (US); Howard LIN, Hopewell Junction, NY (US); Fangchao ZHAO, Hopewell Junction, NY (US); Kerry TICE, Hopewell Junction, NY (US); Timothy CONSIDINE, Hopewell Junction, NY (US); Laurie SZIKLAS, Hopewell Junction, NY (US); Maxim FRAYER, Hopewell Junction, NY (US); Amalkumar P. GHOSH, Hopewell Junction, NY (US); Tim BRAUN, Hopewell Junction, NY (US)

(21) Appl. No.: 18/229,676

(22) Filed: Aug. 3, 2023

Related U.S. Application Data
(60) Provisional application No. 63/395,085, filed on Aug. 4, 2022.
(60) Provisional application No. 63/418,393, filed on Oct. 21, 2022.

(51) Int. Cl. B05D 1/00

(52) U.S. Cl. CPC B05D 1/60

(57) ABSTRACT

A system for deposition of evaporated material on a substrate is provided. The substrate has a central axis. The system includes an evaporation vacuum chamber, at least one nozzle assembly, and a shadow mask. The nozzle assembly has a three-point plurality of point evaporation sources disposed adjacent to the central axis of the substrate and at a distance from the substrate whereby the nozzle assembly provides for molecules of evaporated material to arrive at the substrate at an incident angle of less than or equal to 5 degrees.

### CROSS-REFERENCE TO RELATED APPLICATIONS

This application claims priority to U.S. Provisional Patent Application Ser. No. 63/395,085, filed Aug. 4, 2022, entitled Nearly Collimated Evaporation System, pending, and to U.S. Provisional Patent Application Ser. No. 63/418,393, filed Oct. 21, 2022, entitled Evaporation Chamber with Central Multiple Sources with Improved Collimation, pending.

### BACKGROUND OF THE INVENTION

The present invention is directed to substrate processing. More particularly, the invention is directed to high resolution, high precision substrate processing using a shadow mask to fabricate a patterned organic light emitting diode (OLED) micro display.

Shadow-mask-based deposition is a process by which a layer of material is deposited onto the surface of a substrate such that the desired pattern of the layer is defined during the deposition process itself. This is deposition technique is sometimes referred to as “direct patterning.”

In a typical shadow-mask deposition process, the desired material is vaporized at a source that is located at a distance from the substrate, with a shadow mask positioned between them. As the vaporized atoms of the material travel toward the substrate, they pass through a set of through-holes in the shadow mask, which is positioned just in front of the substrate surface. The through-holes (i.e., apertures) are arranged in the desired pattern for the material on the substrate. As a result, the shadow mask blocks passage of all vaporized atoms except those that pass through the through-holes, which deposit on the substrate surface in the desired pattern. Shadow-mask-based deposition is analogous to silk-screening techniques used to form patterns (e.g., uniform numbers, etc.) on articles of clothing or stenciling used to develop artwork.

Shadow-mask-based deposition has been used for many years in the integrated-circuit (IC) industry to deposit patterns of material on substrates, due, in part, to the fact that it avoids the need for patterning a material layer after it has been deposited. As a result, its use eliminates the need to expose the deposited material to harsh chemicals (e.g., acid-based etchants, caustic photolithography development chemicals, etc.) to pattern it. In addition, shadow-mask-based deposition requires less handling and processing of the substrate, thereby reducing the risk of substrate breakage and increasing fabrication yield. Furthermore, many materials, such as organic materials, cannot be subjected to photolithographic chemicals without damaging them, which makes depositing such materials by shadow mask a necessity.

Unfortunately, the feature resolution that can be obtained by conventional shadow-mask deposition is diminished due to the fact that the deposited material tends to spread laterally after passing through the shadow mask—referred to as “feathering.” Feathering increases with the magnitude of the separation between the substrate and the shadow mask. To mitigate feathering, this separation is kept as small as possible without compromising the integrity of the chucks that hold the substrate and shadow mask. Still further, any non-uniformity in this separation across the deposition area will give rise to variations on the amount of feathering. Such non-uniformity can arise from, for example, a lack of parallelism between the substrate and shadow mask, bowing or sagging of one or both of the substrate and shadow mask, and the like.

Organic light emitting diode (OLED) displays can be fabricated by a number of methods, including inkjet printing and vacuum deposition through a shadow mask, as discussed above. The former method is widely used in fabrication of large format displays suitable for TV screens. The second method making use of a shadow mask is well suited for small format high resolution microdisplays. A typical OLED stack is a multilayer structure positioned between an anode and a cathode and consists of at least one of each functional layer. Functional layers may include, but are not limited to, hole injection layer, hole transport layer, emitter layer, electron transport layer, and electron injection layer. In the case of tandem devices, the number of functional layers increases proportionally depending on the number of tandem units. Emitter layers may consist of mixture of two or three materials including host material and dopant material. As such, fabrication of an OLED microdisplay requires the deposition of multiple materials on a silicon wafer, where an emitter layer requires simultaneous deposition of host and dopant materials into a single layer to attain thorough mixing on molecular level.

There are two approaches to the simultaneous deposition of two or several materials such as host/hosts and dopant/dopants: one can evaporate from two or several point sources, or from two or several linear sources. In prior art evaporation chambers, point sources are typically positioned on the circumference of the chamber, away from a wafer central axis (see FIG. 1A) upon which deposition is occurring. In the example of FIG. 1A, this may result in limited overlap of the two material plumes. Evaporation from two linear sources horizontally traversing under the wafer, shown in the example of FIG. 1B, may result in sequential depositing of materials, and thus, in less thorough mixing of the two materials on molecular scale.

In addition, the deposition from a point source positioned away from the wafer central axis may create another problem associated with the use of a high-resolution shadow mask. The resolution of microdisplays increases rapidly with more advanced methods becoming available to pattern subpixels to the sizes less than 3.5 micron in the shortest dimension. In the near future, the subpixel dimensions of 2 micron or even less are anticipated. Recent success in direct patterning of OLED microdisplays with red, green and blue subpixels formed side by side can be credited to the development of the advanced high-resolution shadow mask with the openings on the scale of few microns.

The implementation of such a high-resolution shadow mask used for directly patterning the OLED faces a number of challenges. Among them is the presence of a small gap between the mask and the wafer, which may result in “feathering” (discussed above), when the evaporated material arriving at the wafer at an angle spreads beyond the area outlined by a subpixel (see FIG. 2). For a high fill-factor microdisplay, the open space between two neighboring sub-pixels may be in the order of a micrometer or less. In such an arrangement, reduction of the deposited material spread to a minimum is therefore required. From a practical standpoint, feathering cannot be tolerated if it exceeds half of the distance between the two neighboring subpixels. For example, if the distance between two neighboring subpixels is in the order of a micrometer, the feathering distance must be half of a micrometer or less. FIG. 3 shows a graph of feathering distance versus the mask-to-wafer gap varied between 1 and 10 micrometers for 2 incident angles of 5 and 10 degrees, respectively. In this example, the feathering threshold is set at 0.5 micrometers. For an incident angle of 5 degree, the mask-to-wafer gap has to be equal or less than 6 micrometers. Correspondingly, for the incident angle of 10 degree, the gap cannot be larger than 3 micrometers.

The deposition from a point source as it is shown in FIG. 1A, will result in the incident angle higher than the angle threshold of 5° leading to unacceptable level of feathering.

### SUMMARY OF THE INVENTION

The present invention is directed to a system for deposition of evaporated material on a substrate. The substrate has a central axis. The system includes an evaporation vacuum chamber, at least one nozzle assembly, and a shadow mask. The nozzle assembly has a plurality of point evaporation sources disposed adjacent to the central axis of the substrate and at a distance from the substrate whereby the nozzle assembly provides for molecules of evaporated material to arrive at the substrate at an incident angle of less than or equal to 5 degrees.

The substrate my have a diameter of 200 mm, wherein a throw distance between each of the plurality of evaporation sources and the substrate is 1,200 mm or greater. The nozzle assembly may provide an overlap of a plurality of evaporating material plumes originating from a point located near the central axis of the substrate. The point evaporation sources may be separated from each other by a like plurality of actively water-cooled partitions to reduce thermal cross talk between sources. The water-cooled partitions may have built-in channels to propagate water flow delivered from an external chiller unit. The water-cooled partitions may be adapted to keep temperature at approximately 20 degrees C. to 30 degrees C. Each of the plurality of point evaporation sources may comprise a plurality of nozzles in a bundle close to each other and equidistant from the substrate to provide good mixing of evaporated materials on a molecular level via merging of individual material plumes into a single plume. There may be, for example, three or four bundles of the point evaporation sources.

Each bundle may be disposed on one of a plurality of swinging arms. Each swing arm may be driven by step motor for positioning of the bundle adjacent to the central axis of the substrate. The step motor located outside said vacuum chamber, where motion is executed using a belt drive through a seal.

### BRIEF DESCRIPTION OF THE DRAWINGS

FIG. 1A is a simplified schematic diagram of a prior art combination of two point sources positioned away from a wafer central axis resulting in limited overlap of the two material plumes and also large incident angle of material molecules arriving at the substrate (wafer).

FIG. 1B is a simplified schematic diagram depicting a prior art system for evaporation from two linear sources horizontally traversing under the substrate which results in sequential depositing materials, and thus, in less thorough mixing of the two materials on molecular scale.

FIG. 2 is a simplified schematic diagram depicting feathering, i.e., unwanted deposition of evaporated material in the area between subpixels. The evaporated material arrives at the wafer under the angle through the shadow mask opening due to the presence of the gap between shadow mask and wafer.

FIG. 3 depicts a graph of an example of feathering distance calculated for two angles as wafer-to-mask gap is varied between 1 and 10 micrometers.

FIG. 4A is a simplified schematic diagram depicting throw distance, i.e., the distance between the evaporation source nozzle and the wafer.

FIG. 4B depicts a graph of an example of incident angle at a 200 mm wafer edge vs. throw distance H. The angle equal or less than the threshold angle of 5 degrees in this example can be attained with the throw distance≥1,200 mm.

FIG. 4C is a graphical illustration of a minimum throw distance for incident angle of less than 5 degrees at a substrate edge for a 75 mm, 100 mm and 300 mm radius substrate for an evaporation system for deposition of evaporated material on a substrate.

FIG. 4D is a table showing a throw distance required for a 5 degree or less deposition angle with the nozzle not positioned at the central axis of the substrate for an evaporation system for deposition of evaporated material on a substrate.

FIG. 5 is a simplified schematic view of a bundle of three point sources with improved collimation resulting in almost complete overlap of three evaporating material plumes leading to thorough mixing on molecular scale in accordance with an exemplary embodiment of the present invention.

FIG. 6 is an isometric view of a bundle of three point sources with improved collimation.

FIG. 6A is a cross sectional elevation view of an evaporation system for deposition of evaporated material on a substrate, having a collimated source nozzle configuration in accordance with an exemplary embodiment of the present invention.

FIG. 7 is an isometric view of a bundle of three collimated point sources on a swinging arm driven by a step motor.

FIG. 8 is a simplified top view of four point-source bundles in a vacuum chamber allowing deposition of twelve materials from a chamber central axis by moving each bundle toward the central axis using four swinging arms driven by four step motors.

FIG. 9 is an isometric bottom view of a vacuum evaporation chamber showing flanges with electrical feedthroughs and four step motors and belt drives to execute motion of swinging arms inside the chamber.

FIG. 10 is a partial side isometric view of a bundle of three point sources in a position under three crystal sensor head assemblies, each containing twelve crystal sensors to set and monitor evaporation rate.

FIG. 11 is a side, elevation view of a vacuum chamber with removable center chimney serving as a shield from an evaporation plume reaching crystal head assemblies. Crystal head assemblies equipped with focusing tubes aligned with the orifices of point sources.

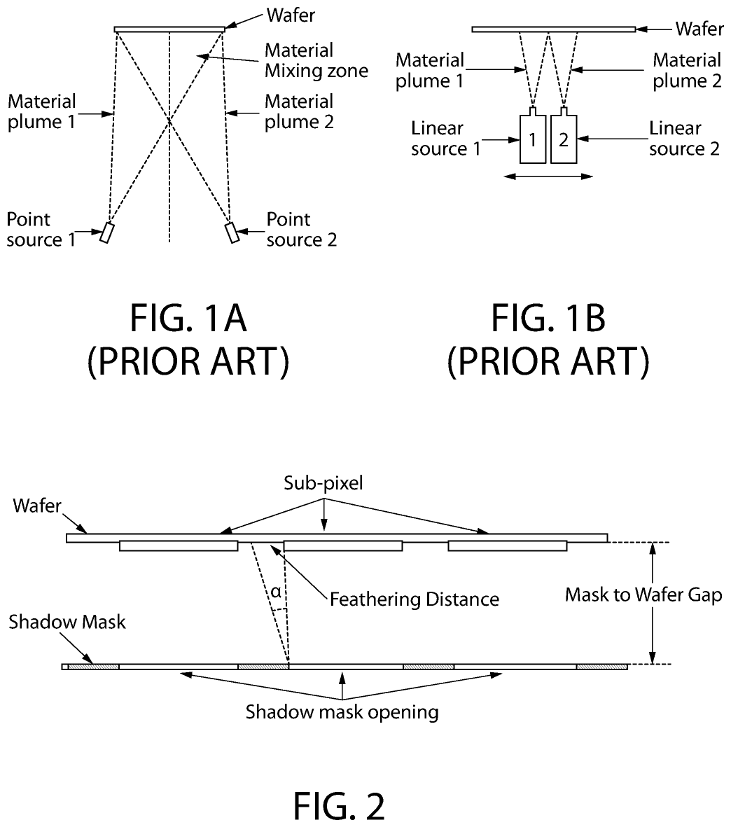

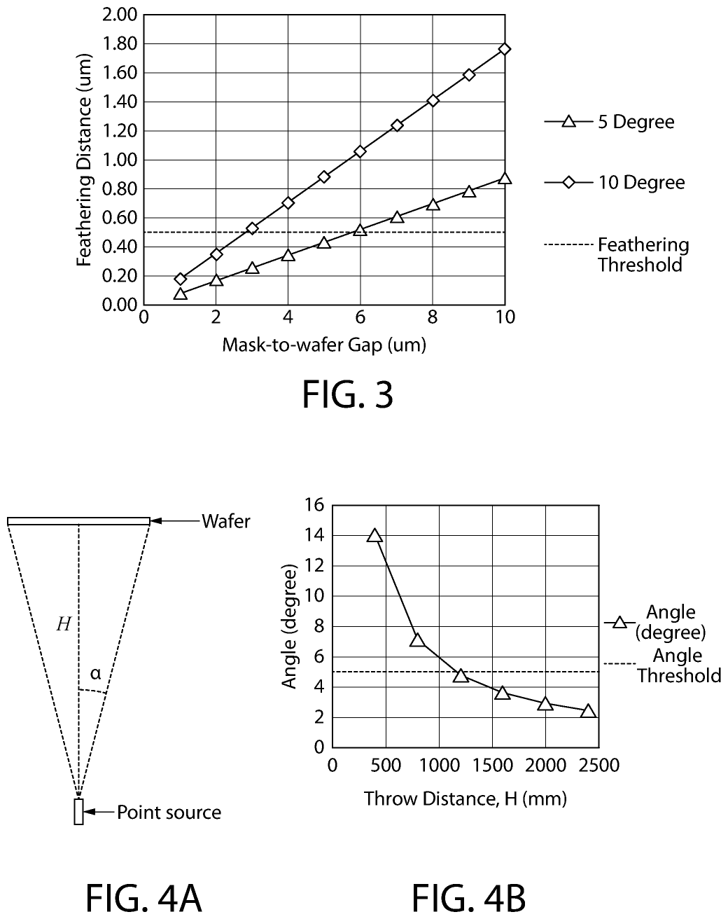

### DETAILED DESCRIPTION

The present invention is directed to high resolution, high precision substrate processing using a shadow mask to fabricate, for example, a patterned organic light emitting diode (OLED) micro display. Shadow-mask-based (i.e., direct pattern) deposition is a process by which a layer of material is deposited onto the surface of a substrate such that the desired pattern of the layer is defined during the deposition process itself.

The desired material is vaporized at a source that is located at a distance from the substrate, with a shadow mask positioned between them. As the vaporized atoms of the material travel toward the substrate, they pass through a set of through-holes in the shadow mask, which is positioned just in front of the substrate surface. The through-holes (i.e., apertures) are arranged in the desired pattern for the material on the substrate. As a result, the shadow mask blocks passage of all vaporized atoms except those that pass through the through-holes, which deposit on the substrate surface in the desired pattern.

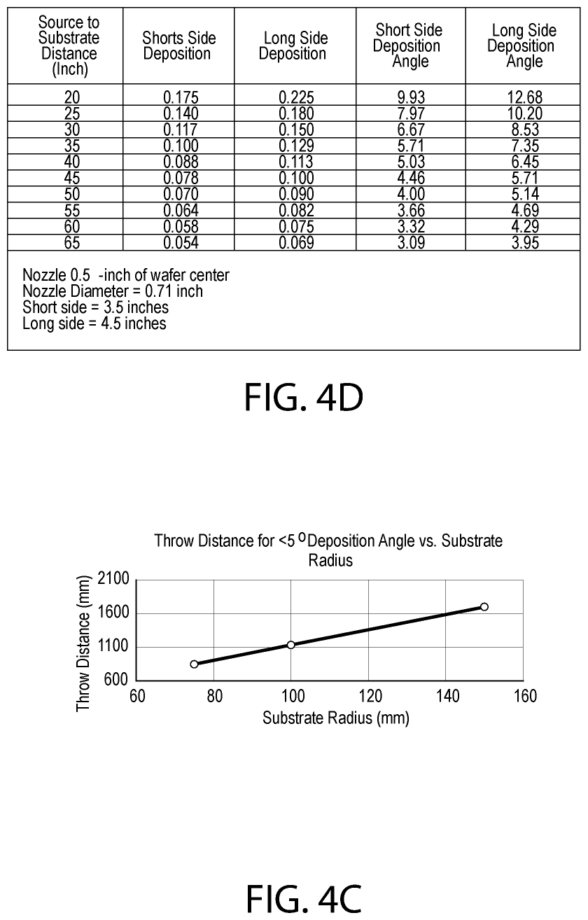

An additional factor affecting the incident angle is throw distance, i.e., the distance H between the evaporation source nozzle and the wafer. See FIG. 4A which is a graphical illustration of an incident angle at a substrate edge as a function of throw distance and substrate radius. The dependence of the incident angle α at the edge of 200 mm wafer on the throw distance is plotted in FIG. 4B. Since the molecules travel in a straight line in low vacuum, to attain the angle less than 5 degrees at the substrate edge (all other locations on the substrate away from the edge will have smaller deposition angle), the throw distance must be greater than 1,135 mm. Fortunately, the mean free path of a molecule in a 10E-6 or 10E-7 Torr pressure is up to 60 meters. FIG. 4C is a graphical illustration of a minimum throw distance for incident angle of less than 5 degrees at a substrate edge for a 75 mm, 100 mm and 300 mm radius substrate. FIG. 4D is a table showing a throw distance required for a 5 degree or less deposition angle with the nozzle not positioned at the central axis of the substrate.

Therefore, to attain an angle of less than or equal to 5° at the wafer edge (all locations on the wafer away from the edge will have even lesser angle), the throw distance in excess of −1,200 mm is required. Another benefit of placing the evaporation source considerably away from the wafer is reduction of exposure of the wafer to radiative heat emanating from the source. When a heated source is in close proximity of the wafer, radiative heat may inadvertently affect alignment of the high-resolution shadow mask to the wafer due to thermal expansion processes. This is eliminated with the source located at long throw distance.

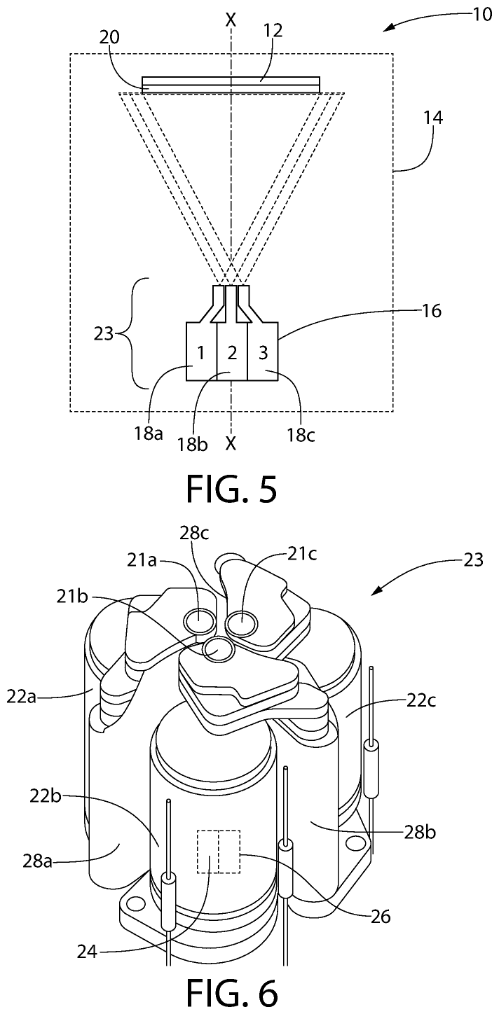

Referring now to the drawing figures, wherein like reference numbers refer to like elements throughout the several views, there is shown in FIG. 5 a system 10 for deposition of evaporated material on a substrate (wafer) 12 in accordance with an exemplary embodiment of the present invention. The system 10 includes an evaporation vacuum chamber 14, a nozzle assembly 16 having a plurality of collimated point evaporation sources 18a, 18b, 18c, and a shadow mask 20.

As shown, a solution to the problem of attaining full overlap of plumes originating from several point sources in accordance with the present invention is to place the point evaporation sources 18a, 18b, 18c in the center of the evaporation vacuum chamber 14, i.e., on the central axis X of the substrate 12 or in close proximity to it. For purposes of the present invention, the term “central axis” means generally on or near the central axis of the substrate. In addition, to form a small incident angle of depositing material on the wafer, which is suitable for a mask-to-wafer gap of few micrometers, in accordance with the present invention, the point evaporation sources 18a, 18b, 18c are placed at a throw distance of >1,200 mm for a substrate having a 200 mm diameter.

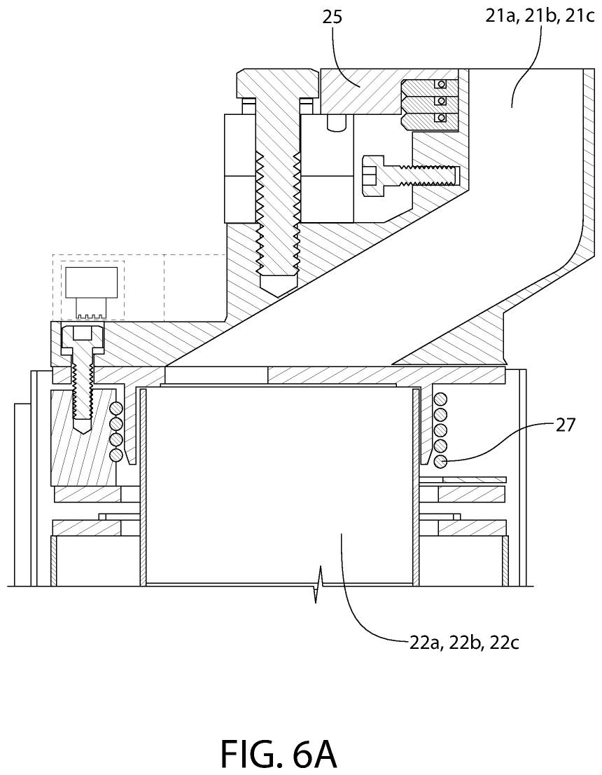

This can be achieved by implementing collimated point evaporation sources 18a, 18b, 18c equipped with nozzles 21a, 21b, 21c of small orifices as shown in FIG. 6. Offsetting of the nozzles 21a, 21b, 21c from the central axis X of each crucible 22a, 22b, 22c allows bringing the nozzle orifices very close to each other. As such, the assembly of the three point evaporation sources 18a, 18b, 18c in a single bundle 23 provides for extremely good mixing of evaporated materials on a molecular level via merging individual material plumes into a single plume (see FIG. 5). This is important for, for example, combining two host materials and a single dopant material, or vice versa, i.e., combining a single host material and two dopant materials.

The assembly of the present invention of three point evaporation sources 18a, 18b, 18c as shown in FIG. 5 includes the three nozzles 21a, 21b, 21c, the three crucibles (i.e., material containers) 22a, 22b, 22c with heaters 24 and thermocouples 26 (only shown with respect to one point evaporation source) to control evaporating material temperature in each crucible, three top nozzle heaters 25, three bottom nozzle heaters 27—each equipped with thermocouples to monitor and control temperature of the nozzle up to 400° C., and three active water-cooled partitions 28a, 28b, 28c to prevent thermal cross talk. See FIG. 6A.

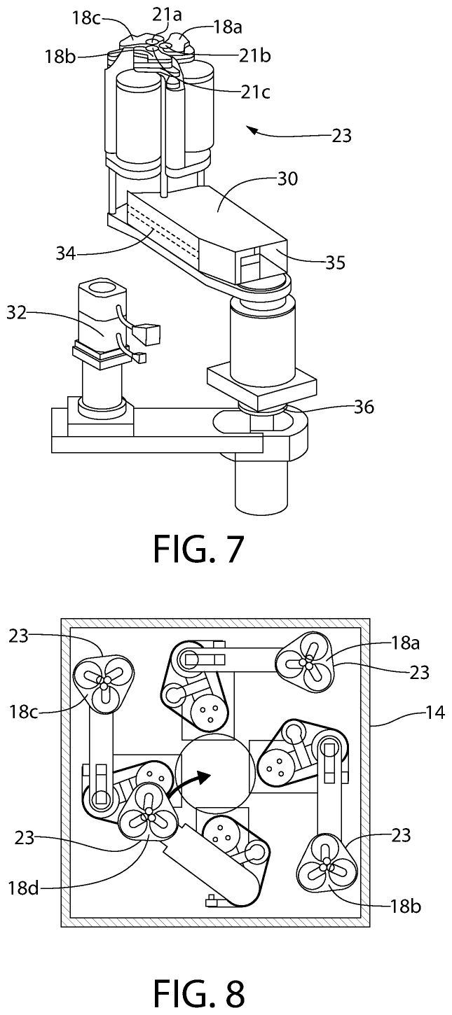

FIG. 7 shows a schematic diagram of the bundle 23 of three point evaporation sources 18a, 18b, 18c on a swinging arm 30 driven by a step motor 32. The swinging arm 30 includes a wire conduit 34 allowing electrical and thermocouple connections to the point evaporation sources 18a, 18b, 18c. In addition, the swinging arm 30 is equipped with a water line 35 connected to the water-cooled partitions of the source bundle. The step motor 32 is located outside the vacuum chamber 14 (not shown in FIG. 7), and activates the swinging arm 30 motion through the feedthrough separating vacuum chamber side of the assembly via a seal 36, e.g., a Ferrotec® seal.

FIG. 8 shows a schematic diagram of four bundles 23 of point evaporation sources 18a, 18b, 18c, 18d on four swinging arms 30 allowing motion of each bundle from park position (as shown with respect to point evaporation sources 18a, 18b and 18c) in vicinity of the wall to the central axis X of the substrate 12 where evaporation of three materials is executed (point evaporation source 18d is shown moving toward the central axis in direction Y). In use, one of the four bundles moves into position at the central axis X.

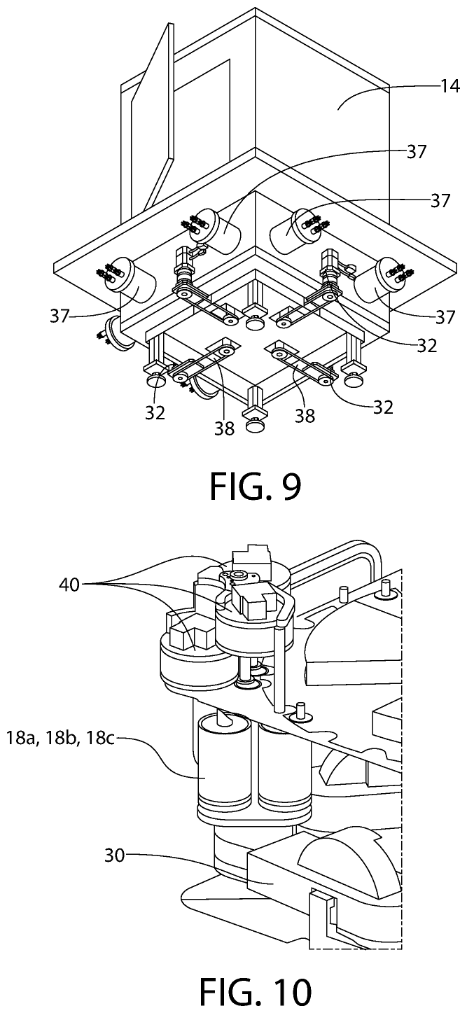

FIG. 9 shows a system 10 bottom view with flanges 37 consisting of electrical feedthroughs and four step motors 32 and belt drives 38 to execute motion of the swinging arms 30 inside the vacuum chamber 14.

FIG. 10 shows three point evaporation sources 18a, 18b, 18c in the position under three crystal sensor head assemblies 40, each containing twelve crystal sensors to set and monitor evaporation rate.

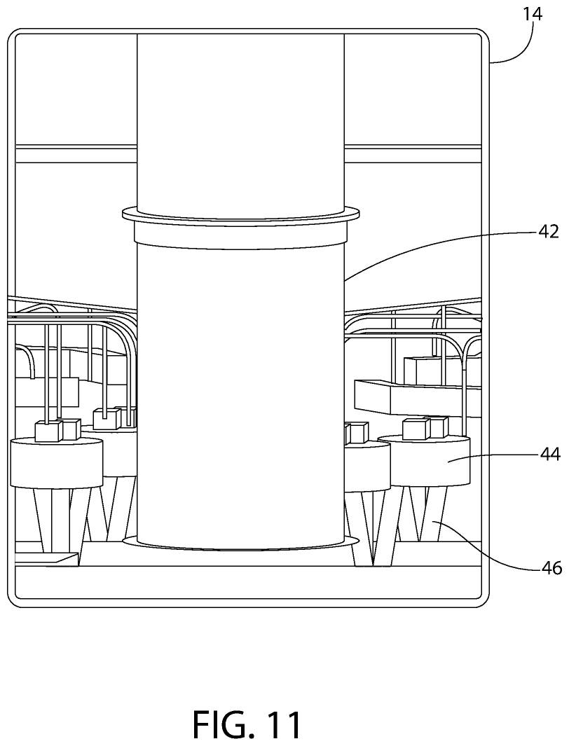

FIG. 11 shows the vacuum chamber 14 with a removable center chimney 42 serving as a shield from evaporation plume reaching crystal head assemblies 44. Crystal head assemblies 44 are equipped with focusing tubes 46 aligned with the orifices of point evaporation sources 18a, 18b, 18.

It is to be understood that the disclosure teaches just one example of the illustrative embodiment and that many variations of the invention can easily be devised by those skilled in the art after reading this disclosure and that the scope of the present invention is to be determined by the following claims.

What is claimed is:

1. A system for deposition of evaporated material on a substrate, the substrate having a central axis, the system comprising:
(a) an evaporation vacuum chamber;
(b) at least one nozzle assembly having a plurality of point evaporation sources, the point evaporation sources disposed adjacent to the central axis of the substrate and at a distance from the substrate whereby the nozzle assembly provides for molecules of evaporated material to arrive at the substrate at an incident angle of less than or equal to 5 degrees; and
(c) a shadow mask disposed adjacent to the substrate.

2. The system for deposition of evaporated material on a substrate of claim 1, wherein the substrate has a diameter of 200 mm and wherein a throw distance between each of the plurality of evaporation sources and the substrate is 1,200 mm or greater.

3. The system for deposition of evaporated material on a substrate of claim 1, wherein the nozzle assembly provides an overlap of a plurality of evaporating material plumes originating from a point located near the central axis of the substrate.

4. The system for deposition of evaporated material on a substrate of claim 1, wherein the point evaporation sources are separated from each other by a like plurality of actively water-cooled partitions to reduce thermal cross talk between sources.

5. The system for deposition of evaporated material on a substrate of claim 4, wherein the water-cooled partitions have built-in channels to propagate water flow delivered from an external chiller unit.

6. The system for deposition of evaporated material on a substrate of claim 5, wherein the water-cooled partitions are adapted to keep temperature at approximately 20 degrees C. to 30 degrees C.

7. The system for deposition of evaporated material on a substrate of claim 1, wherein each of the plurality of point evaporation sources comprise a plurality of nozzles in a bundle close to each other and equidistant from the substrate to provide good mixing of evaporated materials on a molecular level via merging of individual material plumes into a single plume.

8. The system for deposition of evaporated material on a substrate of claim 7, including three bundles of the point evaporation sources.

9. The system for deposition of evaporated material on a substrate of claim 7, including four bundles of the point evaporation sources.

11. The system for deposition of evaporated material on a substrate of claim 7, wherein each bundle is disposed on one of a plurality of swinging arms.

12. The system for deposition of evaporated material on a substrate of claim 11, wherein each swing arm is driven by step motor for positioning of the bundle adjacent to the central axis of the substrate.

13. The system for deposition of evaporated material on a substrate of claim 12, wherein the step motor located outside said vacuum chamber, where motion is executed using a belt drive through a seal.
